(19) United States
(12) Patent Application Publication
(10) Pub. No.: US 2024/0332406 A1
(43) Pub. Date: Oct. 3, 2024

(54) TRANSISTOR MANUFACTURING METHOD

(71) Applicant: STMicroelectronics International N.V., Geneva (CH)

(72) Inventors: Alexis GAUTHIER, Meylan (FR); Pascal CHEVALIER, Chapareillan (FR); Olivier WEBER, Grenoble (FR); Franck ARNAUD, St. Nazaire les Eymes (FR)

(73) Assignee: STMicroelectronics International N.V., Geneva (CH)

(21) Appl. No.: 18/610,829

(22) Filed: Mar. 20, 2024

(30) Foreign Application Priority Data
Mar. 27, 2023 (FR) 2302895

(51) Int. Cl. H01L 29/739; H01L 29/66

(52) U.S. Cl. CPC H01L 29/7394; H01L 29/66325

(57) ABSTRACT

A bipolar transistor includes a first PN junction and a second PN junction. A first gate is located on the first PN junction. A second gate is located on the second PN junction.

### PRIORITY CLAIM

This application claims the priority benefit of French Application for U.S. Pat. No. 2,302,895, filed on Mar. 27, 2023, the content of which is hereby incorporated by reference in its entirety to the maximum extent allowable by law.

### TECHNICAL FIELD

The present disclosure generally concerns electronic devices and, in particular, to electronic devices comprising bipolar transistors and their manufacturing methods.

### BACKGROUND

A bipolar transistor is a semiconductor-based electronic device of the family of transistors. Its operating principle is based on two PN junctions, one forward and the other in reverse.

The dimensions of electronic components such as bipolar transistors are decreased for each generation of components. However, current technologies, in particular technologies of masking during the doping of semiconductor materials, do not enable to ensure the necessary accuracy. Indeed, errors in the placing of the openings of masks may cause non-adapted dopings and thus non-optimized transistors.

There is a need in the art to overcome all or part of the disadvantages of known bipolar transistor manufacturing methods.

### SUMMARY

An embodiment provides a bipolar transistor comprising a gate on each PN junction.

Another embodiment provides a method of manufacturing a bipolar transistor comprising the forming of a gate on each PN junction.

According to an embodiment, the transistor comprises a first PN junction between an emitter semiconductor region and a base semiconductor region having a first gate located thereon and a second PN junction between the base semiconductor region and a collector semiconductor region having a second gate located thereon.

According to an embodiment, each gate comprises a stack of a lower insulating layer and of at least one upper conductive layer and comprises spacers located on the lateral walls of the stack.

According to an embodiment, each gate comprises a stack of a lower insulating layer, an intermediate metal layer, and an upper polysilicon layer and comprises spacers located on the lateral walls of the stack.

According to an embodiment, each gate is configured to be biased.

According to an embodiment, each gate is configured to be floating.

According to an embodiment, the transistor is separated from a substrate by an insulating layer, the substrate being configured to be biased.

According to an embodiment, the method comprises the forming of first, second, and third semiconductor regions respectively at the locations of the emitter, base, and collector regions.

According to an embodiment, the forming of the first, second, and third regions comprises, before the forming of the gates, the forming of a first semiconductor layer having the gates formed thereon, and comprises, after the forming of the gates, an epitaxial growth of the first semiconductor layer to form the first, second, and third regions.

According to an embodiment, method comprises, before the forming of the gates, the forming of a fourth silicon-germanium region in the first layer, each of the first and second gates being located on an edge of the fourth region.

According to an embodiment, the transistor comprises an insulating layer separating the first, second, and third regions from a substrate and comprising a fifth region configured to allow the biasing of the substrate.

According to an embodiment, the method comprises the forming of a first doping mask, comprising a first opening exposing the first region and having its wall closest to the base region located in front of the first gate.

According to an embodiment, the method comprises the forming of a second doping mask, comprising a second opening exposing the second region, the wall of the second opening closest to the emitter region being located in front of the first gate and the wall of the second opening closest to the collector being located in front of the second gate.

According to an embodiment, the method comprises the forming of a third doping mask, comprising a third opening exposing the third region and having its wall closest to the base located in front of the second gate.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an embodiment of a bipolar transistor; and

FIGS. 2 to 14 shows steps of an implementation mode of a bipolar transistor manufacturing method.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

During the forming of bipolar transistors, the base, collector, and emitter regions are formed one after the others by the forming of a mask having an opening exposing the region to be doped and the doping through the opening.

To address the risk of misalignment of said masks, the embodiments described hereafter provide forming gates on the PN junctions of the bipolar transistor. The dimensions of each gate are selected to be able to compensate for the mask placing errors for the doping steps.

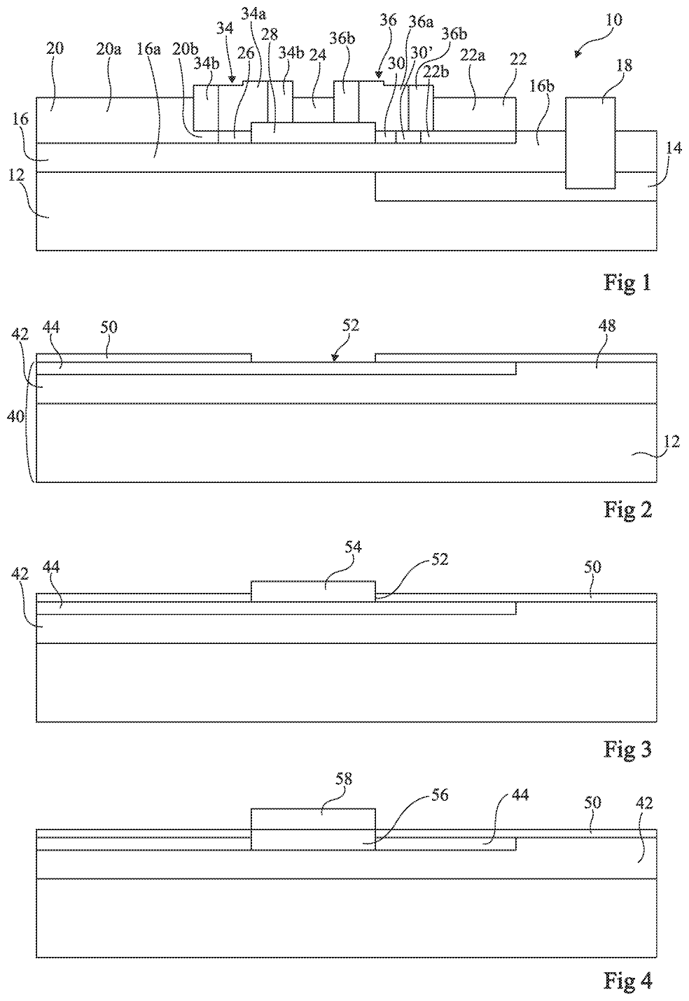

FIG. 1 shows an embodiment of a bipolar transistor 10.

Bipolar transistor 10 is located inside and on top of a semiconductor substrate 12. Substrate 12 is, for example, made of silicon. Substrate 12 comprises, for example, a doped region 14, for example more heavily doped than the rest of substrate 12. Region 14 has, for example, a dopant concentration in the range from 1×10¹⁶ at/cm³ to 1×10²⁰ at/cm³. Region 14 is preferably flush with an upper surface of substrate 12.

Substrate 12 is covered with an insulating layer 16, for example made of silicon oxide. Layer 16 preferably entirely covers substrate 12. Layer 16 preferably comprises a first portion 16a, for example having a substantially constant thickness, for example in the range from 20 nm to 40 nm, and a second portion 16b, for example having a thickness greater than the thickness of first portion 16a, for example in the range from 30 nm to 50 nm. Portion 16b at least partially faces region 14.

A semiconductor region 18 crosses through insulating region portion 16b to reach region 14. Region 18, for example, partially extends into region 14. Region 18 comprises, for example, an upper portion extending above the upper surface of portion 16b. Preferably, region 18 is made of the same material as substrate 12. Region 18 is, for example, doped with the same conductivity type as region 14.

Transistor 10 comprises an emitter region 20. Region 20 is a semiconductor region, for example made of the same material as substrate 12, for example made of silicon. Region 20 is doped, for example, with the same conductivity type as regions 14 and 18.

Region 20 is located, for example entirely, on portion 16a. Region 20 is, for example, in contact with the upper surface of portion 16a of layer 16.

Region 20 comprises, for example, two portions 20a and 20b. Each of portions 20a and 20b has, for example, a substantially constant thickness. The thickness of portion 20a is greater than the thickness of portion 20b. Portion 20a has, for example, a thickness in the range from 15 nm to 25 nm, for example substantially equal to 25 nm, and portion 20b for example has a thickness in the range from 5 nm to 15 nm, for example substantially equal to 8 nm. Laterally, that is, in a plane parallel to the upper surface of substrate 12, portion 20a has, for example, a width in the range from 90 nm to 110 nm, for example substantially equal to 103 nm, and portion 20b has, for example, a width in the range from 10 nm to 20 nm, for example substantially equal to 17 nm.

Similarly, transistor 10 comprises a collector region 22. Region 22 is a semiconductor region, for example made of the same material as substrate 12, for example made of silicon. Region 22 is doped, for example with the same conductivity type as regions 14, 18, and 20.

Region 22 is located, for example entirely, on portion 16b. Region 22 is, for example, in contact with the upper surface of portion 16b of layer 16.

Region 22 comprises, for example, two portions 22a and 22b. Each of portions 22a and 22b has, for example, a substantially constant thickness. The thickness of portion 22a is greater than the thickness of portion 22b. Portions 20a and 22a have, for example, an identical a thickness. Portions 20b and 22b have, for example, an identical thickness. Portion 22a has, for example, a thickness in the range from 15 nm to 25 nm, for example substantially equal to 25 nm, and portion 22b has, for example, a thickness in the range from 5 nm to 15 nm, for example substantially equal to 8 nm. Laterally, that is, in a plane parallel to the upper surface of substrate 12, portion 22a has, for example, a width in the range from 50 nm to 75 nm, for example substantially equal to 65 nm, and portion 22b has, for example, a width in the range from 1 nm to 15 nm, for example substantially equal to 8 nm.

Regions 20 and 22 are formed in such a way that portions 20b and 22b are located one towards the other. Thus, portions 20a and 22a are separated from each other by portions 20b and 22b. Regions 20 and 22 are not in contact with each other.

Transistor 10 comprises, for example, a semiconductor region 26. Region 26 is, for example, made of the same material as region 20, for example made of silicon. Region 26 is, for example, not doped. Region 26 is located on portion 16a. Region 26 is located between region 22 and region 20, preferably between portion 22b and portion 20b. Region 26 is, for example, in contact with a lateral surface, preferably with the entire lateral surface, of portion 20b.

Region 26 has, for example, a substantially constant thickness, for example substantially equal to the height of portion 20b. Region 26 has, for example, a width in the range from 25 nm to 60 nm.

Transistor 10 comprises, for example, a semiconductor region 30. Region 30 is, for example, made of the same material as region 22, for example made of silicon. Region 30 is, for example, not doped, except for a portion 30′. Portion 30′ is, for example, doped with the same conductivity type as region 22. Portion 30′ is, for example, less heavily doped than region 22. Region 30 is located on portion 16a. Region 30 is located between region 20 and region 22, preferably between portion 20b and portion 22b. Region 30 is, for example, in contact with a lateral surface, preferably with the entire lateral surface, of portion 22b. For example, portion 30′ is located between the rest of region 30 and portion 22b. Portion 30′ thus is, for example, in contact with the lateral surface of portion 22b.

Transistor 10 further comprises a region 28. Region 28 is a semiconductor region. Region 28 is, for example, made of silicon-germanium (SiGe). The germanium content is, for example, 23%.

Region 28 is located on portion 16a. Region 28 is located between region 30 and region 26. Region 28 is, for example, in contact with a lateral surface, preferably with the entire lateral surface, of region 26. Region 28 is, for example, in contact with a lateral surface, preferably with the entire lateral surface, of region 30. The portion of the upper surface of portion 16a located between portion 22b and portion 20b is, for example, entirely covered by regions 26, 28, and 30.

Region 28 has, for example, a substantially constant thickness, for example greater than the height of portion 20b and of region 26. The thickness of region 28 is, for example, smaller than the thickness of portion 20a. Region 28 has, for example, a width in the range from 20 nm to 40 nm.

Transistor 10 further comprises a base region 24. Region 24 is located between regions 20 and 22, more precisely between portions 20b and 22b. Region 24 is preferably not in contact with regions 20 and 22. Region 24 is located in front of portion 16a. Region 24 is on region 28, preferably in contact with region 28. Region 28 extends, for example, all the way to the level of the upper surface of portions 20a and 22a. Region 24 has, for example, a width, that is, the dimension in the direction extending between portion 20b and portion 22b, in the range from 50 to 100 nm, for example substantially equal to 78 nm.

Region 30 has, for example, a substantially constant thickness, for example substantially equal to the height of portion 22b. Region 30 has, for example, a width in the range from 25 nm to 60 nm.

Transistor 10 further comprises two gates 34 and 36. Gate 34 is located between the emitter of the transistor, that is, region 20, and the base of the transistor, that is, region 24. Gate 36 is located between the collector of the transistor, that is, region 22, and the base of the transistor, that is, region 24. In particular, gate 34 is located on the interface region between the emitter and the base, that is, on the PN junction between the emitter and the base. Similarly, gate 36 is located on the interface region between the collector and the base, that is, on the PN junction between the collector and the base.

Gate 34, respectively 36, comprises a stack 34a, respectively 36a, of layers not explicitly shown. Each stack 34a or 36a preferably comprises a lower insulating layer covered with a conductive layer. For example, each stack 34a, 36a comprises: a lower layer, that is, the layer closest to substrate 12, made of an insulating material, preferably of a material having a high dielectric constant k, for example greater than 15; an intermediate layer covering, preferably entirely, the lower layer, made of a conductive material, preferably of a metal; and an upper layer, that is, the most distant from substrate 12, covering, preferably entirely, the intermediate layer, made of a conductive material, preferably made of polysilicon.

Gates 34, 36 comprise respective spacers 34b and 36b, covering, preferably entirely, the lateral walls of stacks 34a, 36a.

As region 28 has a greater thickness than regions 26 and 30, Stacks 34a and 36a respectively cover a dropout between the region 28 and the region 26 and between the region 28 and the region 30. Therefore, stacks 34a and 36a each cover a part of the upper face of the region 28 and part of the lateral faces of region 28, which are not covered by the regions 26 and 30. Stacks 34a and 36a preferably have a substantially constant thickness. Therefore, the upper face of stacks 34a and 36a are not planar.

Gate 34 covers portion 20b and regions 26, 28. Gate 34 thus covers the PN junction between the emitter and the base. Gate 34 preferably does not cover portion 20a. Preferably, gate 34 does not cover region 24. Similarly, gate 36 covers portion 22b and region 30′, 30. Gate 36 thus covers the PN junction between the collector and the base. Gate 36 preferably does not cover portion 22a. Preferably, gate 36 does not cover region 24.

Each of gates 34, 36, and more precisely stacks 34a and 36a, is coupled, for example, to a node of application of a bias voltage. Indeed, the biasing of gates 34, 36, and more precisely stacks 34a and 36a, enables to control the electrostatic field generated at the level of regions 26, 28, 30.

Alternatively, gates 34, 36 may be floating, that is, not be biased.

FIGS. 2 to 14 show steps, preferably successive, of an implementation mode of a bipolar transistor manufacturing method.

FIG. 2 shows a device after a step of an implementation mode of a bipolar transistor manufacturing method.

During this step, a stack 40 is formed. Stack 40 comprises semiconductor substrate 12, for example made of silicon, an insulating layer 42, for example made of silicon oxide, and a semiconductor layer 44, for example made of silicon, preferably made of the same material as substrate 12.

Layer 42 has, for example, a substantially constant thickness, for example in the range from 10 to 30 nm, for example equal to 20 nm. Layer 44 has, for example, a substantially constant thickness, for example in the range from 1 to 15 nm, for example substantially equal to 10 nm.

Layer 42 rests on, and is preferably in contact with, an upper surface of substrate 12. Layer 42 preferably entirely covers the upper surface of substrate 12. Similarly, layer 44 rests on, and is preferably in contact with, an upper surface of layer 42. Layer 44 and substrate 12 are thus preferably entirely separated by layer 42. Stack 40 is for example a substrate of semiconductor on insulator (SOI or Silicon On Insulator) type.

The step of FIG. 2 further comprises the oxidation of a portion of layer 44, through a hard mask located on an upper surface of layer 42, to form a portion 48 made of the material of layer 42, for example made of silicon oxide. Portion 48 extends from the upper surface of layer 42 to the upper surface of layer 44.

The step of FIG. 2 then comprises the removal of the hard mask. The removal of the mask may cause the removal of a portion of layer 44 and of portion 48. Preferably, the upper surfaces of layer 44 and of portion 46 are coplanar. Preferably, the thickness of layer 44 is in the range from 7 to 13 nm, for example substantially equal to 8 nm.

The step of FIG. 2 further comprises the forming of a layer 50. Layer 50 preferably entirely covers layer 44. Layer 50 is made of a material enabling to prevent the epitaxy of the material of layer 44. Layer 50 is, for example, made of silicon-germanium. Layer 50 has, for example, a substantially constant thickness in the range from 5 nm to 15 nm, for example substantially equal to 11 nm.

The step of FIG. 2 comprises the forming of an opening 52 in layer 50. Opening 52 covers the location of region 28 and of base region 24.

FIG. 3 shows a device after another step of an implementation mode of a bipolar transistor manufacturing method.

During this step, a region 54 is formed in opening 52. Region 52 is formed by epitaxial growth from layer 44. Region 52 is made of the material of region 28. The thickness of region 54 is, for example, substantially constant, for example in the range from 8 nm to 10 nm, substantially equal to 8.3 nm.

FIG. 4 shows a device after another step of an implementation mode of a bipolar transistor manufacturing method.

During this step, the structure resulting from the step of FIG. 3 is placed in an enclosure reaching a temperature of 1,100° C. As a result, the germanium of region 54 thus migrates, by a condensation phenomenon, into layer 44. Layers 56 and 58 are thus formed.

Layer 56 corresponds to the portion of layer 44 located under region 54 and into which the germanium has migrated. Region 56 further comprises, for example, a lower portion of region 54. Region 56 is made of silicon-germanium. For example, region 56 comprises 23% of germanium. Region 56 extends, for example, from the upper surface of layer 42 to the upper surface of layer 50. The thickness of region 56 is, for example, substantially constant and in the range from 5 nm to 15 nm, for example substantially equal to 10 nm. The lateral dimensions of region 56 correspond, for example, to the dimensions of opening 52.

Region 58 corresponds to the remainders of region 54. Region 58 is, for example, made of silicon oxide. Region 58 covers, preferably entirely, the upper surface of region 56. The thickness of region 58 is, for example, substantially constant and in the range from 10 nm to 20 nm, for example substantially equal to 13 nm. The lateral dimensions of region 58 correspond, for example, to the dimensions of opening 52.

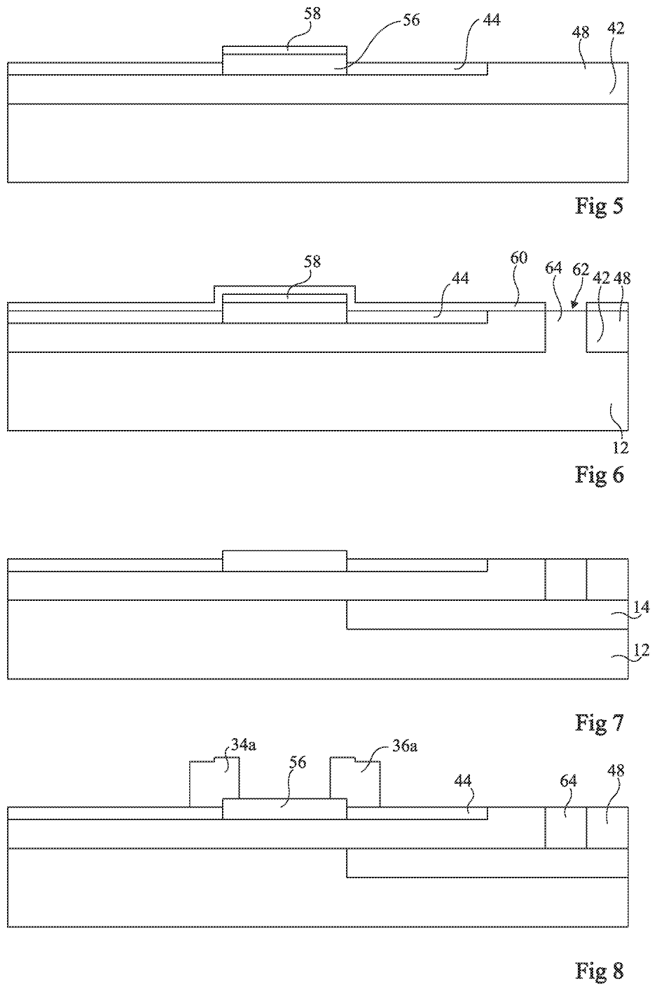

FIG. 5 shows a device after another step of an implementation mode of a bipolar transistor manufacturing method.

During this step, layer 50 is etched. The step of etching of layer 50 causes the partial etching of region 58, of layer 44, and of portion 48. Thus, after the etching of layer 50, the thickness of layer 44 is in the range from 5 nm to 10 nm, for example substantially equal to 8.1 nm, the thickness of region 58 is in the range from 1 nm to 5 nm, for example substantially equal to 3.5 nm, and the thickness of portion 48 is substantially equal to the thickness of layer 44.

FIG. 6 shows a device after another step of an implementation mode of a bipolar transistor manufacturing method.

During this step, a layer 60 is formed on the structure resulting from the step of FIG. 5. An opening 62 is formed in layer 60. Opening 62 is located at the level of the location of region 18. In other words, the lateral dimensions of opening 62 are substantially equal to the dimensions of region 18.

The step of FIG. 6 further comprises a step of etching of layer 42 and of portion 48 through opening 62. Thus, the portions of layer 42 and of portion 48 located at the location of region 18 are etched to expose substrate 12 in front of opening 62.

The step of FIG. 6 then comprises a step of epitaxial growth of the material of substrate 12 at the location of region 18, that is, at the location of the etched portions of layer 42 and of portion 48. A region 64 is thus formed by the epitaxial growth. Region 64 thus extends from the upper surface of substrate 12 to the level of the upper surface of portion 48, that is, the upper surface of layer 44.

FIG. 7 shows a device after another step of an implementation mode of a bipolar transistor manufacturing method.

The step of FIG. 7 comprises the etching of layer 60. The step of FIG. 7 further comprises the forming of region 14 in substrate 12. The forming of region 14 is performed by the doping of the region of substrate 12 corresponding to region 14.

FIG. 8 shows a device after another step of an implementation mode of a bipolar transistor manufacturing method.

During this step, stacks 34a and 36a are formed. More precisely, a stack of layers is generally formed over the structure resulting from the step of FIG. 7. Said stack comprises: a lower layer, that is, the layer closest to substrate 12, made of an insulating material, covering layer 44, region 56, portion 48, and region 64. The lower layer is preferably made of a material having a dielectric constant for example greater than 15. The stack further comprises: an intermediate layer covering, preferably entirely, the lower layer, made of a conductive material, preferably of a metal; and an upper layer, that is, the most distant from substrate 12, covering, preferably entirely, the intermediate layer, made of a conductive material, preferably made of polysilicon.

Said stack is then etched to form stacks 34a and 36a. Stacks 34a and 36a are located on opposite ends of region 56. The stacks thus cover layer 44 and region 56 on either side of the ends of region 56.

Stacks 34a and 36a have, for example, a width, that is, a dimension in the direction from one stack to the other, greater than 50 nm. The width of the stacks is, for example, in the range from 60 nm to 80 nm, for example substantially equal to 70 nm.

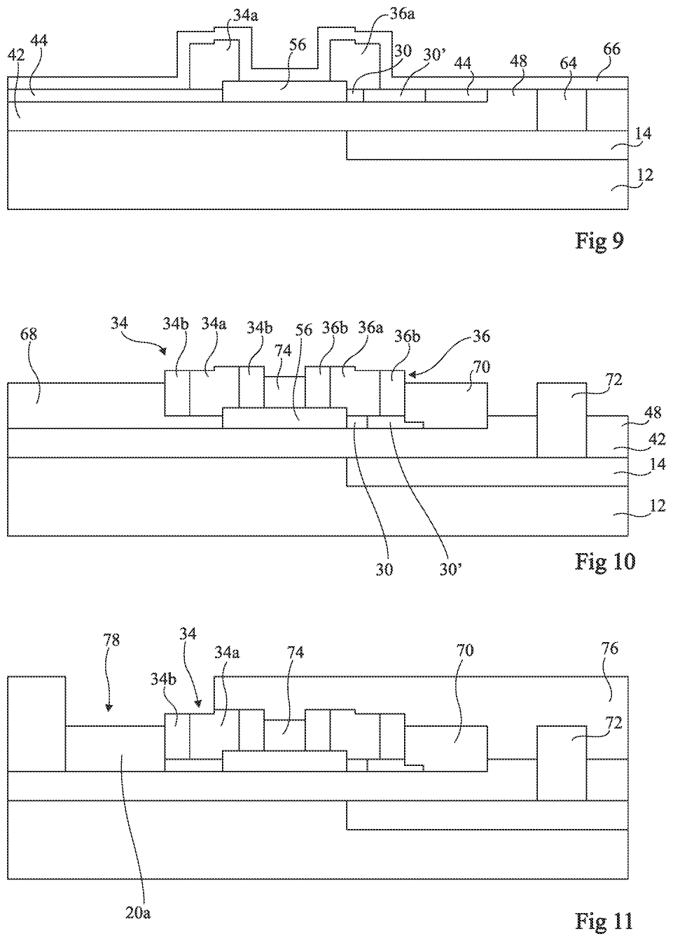

FIG. 9 shows a device after another step of an implementation mode of a bipolar transistor manufacturing method.

During this step, the portion of layer 44 partially located under region 36a is partially doped to form portion 30′. The portion of layer 44 partially located under region 36a thus comprises 30, portion 30′, a portion corresponding to portion 22b, and a portion corresponding to a lower portion of portion 22a.

The step of FIG. 9 further comprises the forming, conformally, of a layer 66 of insulating material over the entire structure resulting from the step of forming of portion 30′. Layer 66 conformally covers the structure. Layer 66 in particular covers the upper surface of layer 44, the walls and the upper surface of stacks 34a and 36a, the upper surface of region 56. Layer 66 is made of the material of spacers 34b and 36b.

FIG. 10 shows a device after another step of an implementation mode of a bipolar transistor manufacturing method.

During this step, spacers 34b and 36b are formed. More precisely, layer 66 is etched by an anisotropic etching to only keep the portions of layer 66 located on the lateral walls, in particular the lateral walls of stacks 34a and 36a. During the step of forming of the spacers, layer 44 may be partially etched. Gates 34 and 36 are thus formed.

The step of FIG. 10 further comprises an epitaxial growth of layer 44 and of regions 56 and 64. The epitaxial growth of layer 44 allows the forming of regions 68 and 70, region 68 being located at the location of region 20 and region 70 being substantially located at the location of portion 22a. The epitaxial growth of region 64 allows the forming of a region 72 located at the location of region 18. The epitaxial growth of region 56 allows the forming of a region 74 located at the location of an upper portion of region 24, a portion of region 56 being located at the location of the rest of region 24.

FIG. 11 shows a device after another step of an implementation mode of a bipolar transistor manufacturing method.

During this step, a self-aligned mask 76 is formed on the structure resulting from the step of FIG. 10. Mask 76 comprises an opening 78 exposing the location of portion 20a. Opening 78 partially exposes gate 34. In other words, a wall of mask 76 located in the opening faces gate 34. Opening 78 does not expose regions 70, 72, and 74.

The step of FIG. 11 further comprises the doping of portion 20a through opening 78. Mask 76 is then removed.

The presence of gate 34 enables to have a margin in the placing of opening 78. In other words, alignment errors of the mask are compensated for by the presence of gate 34. Indeed, the doping does not impact layers made of polysilicon and layers made of insulating materials, for example made of silicon oxide.

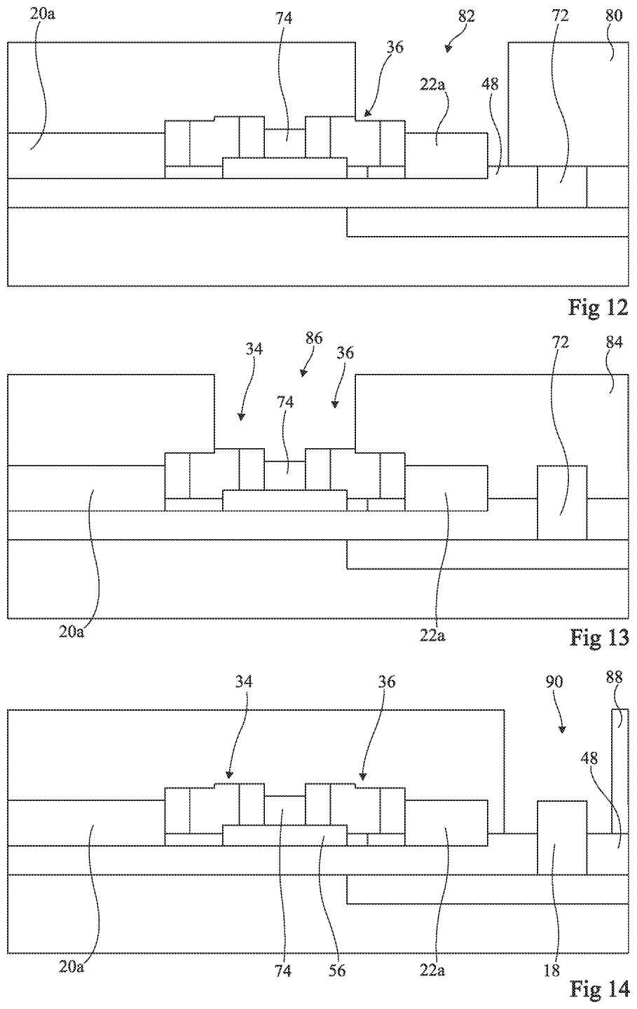

FIG. 12 shows a device after another step of an implementation mode of a bipolar transistor manufacturing method.

During this step, a self-aligned mask 80 is formed on the structure resulting from the step of FIG. 11. Mask 80 comprises an opening 82 exposing the location of portion 22a. Opening 82 partially exposes gate 36. In other words, a wall of mask 80 located in the opening faces gate 36. The opposite wall is located in front of portion 48, made of insulating material. Opening 82 does not expose regions 20a, 72, and 74.

Like the presence of gate 34 in the step of FIG. 11, the presence of gate 36 enables to have a margin in the placing of opening 82. In other words, mask alignment errors are compensated for by the presence of gate 34.

The step of FIG. 12 further comprises the doping of portion 22a through opening 82. Mask 80 is then removed.

FIG. 13 shows a device after another step of an implementation mode of a bipolar transistor manufacturing method.

During this step, a self-aligned mask 84 is formed on the structure resulting from the step of FIG. 12. Mask 84 comprises an opening 86 exposing the location of region 24. Opening 86 partially exposes gates 34 and 36. In other words, a wall of mask 84 located in the opening faces gate 34 and the opposite wall is located in front of gate 36. Opening 86 does not expose region 72 and portions 20a and 22a.

The presence of gates 34 and 36 enables to have a margin in the placing of opening 86. In other words, mask alignment errors are compensated for by the presence of gate 34.

The step of FIG. 13 further comprises the doping of region 74 through opening 86, the doping type corresponding to the doping type of region 24. Mask 84 is then removed.

FIG. 14 shows a device after another step of an implementation mode of a bipolar transistor manufacturing method.

During this step, a self-aligned mask 88 is formed on the structure resulting from the step of FIG. 13. Mask 88 comprises an opening 90 exposing the location of region 72. Opening 90 partially exposes the upper surface of portion 48. In other words, the walls of mask 88 located in the opening face insulating portion 48. Opening 90 does not expose region 74 and portions 20a and 22a.

Mask alignment errors can be compensated for by the presence of the material of portion 48.

The step of FIG. 14 further comprises the doping of region 72 through opening 90, to form region 18. Mask 90 is then removed.

The step of FIG. 14 is, for example, followed by an anneal step, for example at a temperature in the range from 1,000° C. to 1,200° C., for example substantially equal to 1,160° C. During the anneal, the dopants of portions 20a and 20b migrate to form portions 20b and 22b. Similarly, during the anneal, the dopants of region 74 migrate to form region 24.

The method comprises, for example, a step of contact forming on the portions 20b and 22b and on regions 24 and 18. The method may comprise a step of contact forming on stacks 34a and 36a.

An advantage of the described embodiments is that the risk of alignment error of the doping masks is greatly decreased, which ascertains a doping configured to the formation of a bipolar transistor.

Another advantage of the described embodiments is that it is possible to bias the PN junctions, which enables to control the electrostatic field of the PN junctions. It is thus possible to configure the transistor to a high-voltage and low-speed use or to a low-voltage and high-speed use.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A bipolar transistor, comprising:
an insulating layer;
a base region on the insulating layer doped with a first conductivity type;
an emitter region on the insulating layer including a first portion doped with a second conductivity type and a second portion that is not doped, wherein said second portion of the emitter region is in contact with the base region;
a collector region on the insulating layer including a first portion doped with the second conductivity type and a second portion that is not doped, wherein said second portion of the collector region is in contact with the base region;
a first gate extending over the second portion of the emitter region and a first portion of the base region; and
a second gate extending over the second portion of the collector region and a second portion of the base region.

2. The bipolar transistor of claim 1, wherein each of the first and second gates comprises a gate stack including a gate insulator layer and a conducting region over the gate insulator layer.

3. The bipolar transistor of claim 2, wherein the first gate includes a sidewall spacer separating the conducting region from the first portion of the emitter region, and wherein the second gate includes a sidewall spacer separating the conducting region from the first portion of the collector region.

4. The bipolar transistor of claim 1, wherein each of the first and second gates comprises a gate stack including a gate insulator layer, an intermediate metal layer over the gate insulator layer and an upper polysilicon layer over the intermediate metal layer.

5. The bipolar transistor of claim 4, wherein the first gate includes a sidewall spacer separating the intermediate metal layer and upper polysilicon layer from the first portion of the emitter region, and wherein the second gate includes a sidewall spacer separating the intermediate metal layer and upper polysilicon layer from the first portion of the collector region.

6. The bipolar transistor of claim 1, wherein the base region comprises a stack of a silicon-germanium region and an epitaxial region over the silicon-germanium region.

7. The bipolar transistor of claim 6, wherein a thickness of the silicon-germanium region is thicker than a thickness of either of the second portion of the emitter region or the second portion of the collector region.

8. The bipolar transistor of claim 7, wherein each of the first and second gates comprises a gate stack, and wherein an upper surface of the gate stack has a step change due the thickness differences of the silicon-germanium region compared to either of the second portion of the emitter region or the second portion of the collector region.

9. The bipolar transistor of claim 7, wherein the first gate includes a sidewall spacer separating the gate stack from the epitaxial region, and wherein the second gate includes a sidewall spacer separating the gate stack from the epitaxial region.

10. The bipolar transistor according to claim 1, wherein each of the first gate and second gate is configured to be biased.

11. The bipolar transistor according to claim 1, wherein each of the first gate and second gate is configured to be floating.

12. The bipolar transistor according to claim 1, wherein the insulating layer is supported by a substrate, and wherein the substrate is being configured to be biased.

13. The bipolar transistor according to claim 12, wherein a more heavily doped region of the substrate is configured to be biased, and wherein said more heavily doped region of the substrate is located below the collector region, but wherein said more heavily doped region of the substrate does not extend under the emitter region.

14. The bipolar transistor according to claim 13, further comprising a doped contact region extending through the insulating layer to the more heavily doped region of the substrate.

15. The bipolar transistor according to claim 1, wherein said second gate further extends over a part of the first portion of the collector region, but wherein said first gate does not extend over a part of the first portion of the emitter region.

16. The bipolar transistor according to claim 1, wherein the first gate does not extend over the first portion of the emitter region, and wherein the second gate extends at least partially over the first portion of the collector region.
